(19) United States
(12) Patent Application Publication
(10) Pub. No.: US 2026/0278203 A1
(43) Pub. Date: Sep. 17, 2026

(54) MANAGEMENT APPARATUS, ENERGY STORAGE APPARATUS AND VOLTAGE SIMULATION METHOD

(71) Applicant: GS Yuasa International Ltd., Kyoto-shi, Kyoto (JP)

(72) Inventor: Satoshi KUNITA, Kyoto-shi, Kyoto (JP)

(21) Appl. No.: 18/871,976

(22) PCT Filed: May 26, 2023
(86) PCT No.: PCT/JP2023/019600

§ 371 Date: Dec. 5, 2024

(30) Foreign Application Priority Data
Jun. 6, 2022 (JP) 2022-091447

(51) Int. Cl. G06F 30/20

(52) U.S. Cl. CPC G06F 30/20

(57) ABSTRACT

A management apparatus 130 that periodically executes voltage simulation for an energy storage apparatus 50 includes: an arithmetic portion 131; and a storage portion 132. The storage portion 132 stores a discharge pattern P made of time series data for discharge current. The discharge pattern P includes first time series data D1 and second time series data D2 for the discharge current, the first time series data D1 is time series data for the discharge current, for a predetermined time, and the second time series data D2 is time series data for the discharge current, within a voltage simulation execution period for the energy storage apparatus. The arithmetic portion 131 periodically executes voltage simulation for estimating a voltage change of the energy storage apparatus 50 when the energy storage apparatus discharges in the discharge pattern P, and periodically judges whether the energy storage apparatus can discharge in the discharge pattern P, based on a result of the voltage simulation.

### CROSS REFERENCE TO RELATED APPLICATIONS

This application is a National Stage Application, filed under 35 U.S.C. § 371, of International Application No. PCT/JP2023/019600, filed May 26, 2023, which international application claims priority to and the benefit of Japanese Application No. 2022-091447, filed Jun. 6, 2022; the contents of both of which as are hereby incorporated by reference in their entireties.

### BACKGROUND

### Technical Field

The present invention relates to voltage simulation of an energy storage apparatus.

### Description of Related Art

Energy storage apparatuses are used for various applications, such as power sources of mobile bodies represented by automobiles, etc., or for energy storage for photovoltaic power generation systems (refer to Patent Literatures: JP2017-5985 and JP2019-126110).

### BRIEF SUMMARY

One function of an energy storage apparatus is voltage simulation. The voltage simulation is to estimate a voltage change of the energy storage apparatus when discharge is performed in a predetermined discharge pattern. For example, in a case of an energy storage apparatus for automobiles, a result of the voltage simulation is used to judge whether discharge is possible in the discharge pattern.

By periodically executing voltage simulation, it is possible to periodically confirm whether discharge in a discharge pattern is possible. The voltage simulation is not limited for use in automobiles, however is also applicable for other purposes such as for energy storage for photovoltaic power generation systems.

However, if an energy storage apparatus is discharging within a voltage simulation execution period, misjudgment as to whether discharge is possible likely to happen.

The present invention has a problem of restraining misjudgment as to whether discharge is possible in a discharge pattern.

An overview of a management apparatus is described. The management apparatus periodically executes voltage simulation for an energy storage apparatus. The management apparatus includes an arithmetic portion and a storage portion. Voltage simulation for an energy storage apparatus may be voltage simulation for an external terminal or voltage simulation for a cell or a battery pack.

The storage portion stores a discharge pattern made of time series data for discharge current. The discharge pattern includes first time series data and second time series data for discharge current. The first time series data is time series data for the discharge current, for a predetermined time, and the second time series data is time series data for the discharge current, within a voltage simulation execution period for the energy storage apparatus.

The arithmetic portion periodically executes voltage simulation for estimating a voltage change of the energy storage apparatus when the energy storage apparatus discharges in the discharge pattern, and periodically judges whether the energy storage apparatus can discharge in the discharge pattern, based on a result of the voltage simulation.

The present technique can be applied to a voltage simulation method and a voltage simulation program.

The present technique can restrain misjudgment as to whether discharge is possible in a discharge pattern.

### BRIEF DESCRIPTION OF THE FIGURES

FIG. 1 is a side view of an automobile.

FIG. 2 is an exploded perspective view of a battery.

FIG. 3 is a plan view of a secondary battery cell.

FIG. 4 is a sectional view of FIG. 3 at A-A line.

FIG. 5 is a block diagram illustrating an electrical configuration of the battery.

FIG. 6A illustrates a waveform of a discharge pattern before improvement.

FIG. 6B illustrates a waveform of the discharge pattern after the improvement.

FIG. 7 illustrates a timeline of voltage simulation.

FIG. 8 illustrates a voltage estimation result by voltage simulation.

FIG. 9 illustrates a voltage estimation result by voltage simulation.

FIG. 10 illustrates input/output to/from an arithmetic portion.

FIG. 11 illustrates a voltage simulation execution period.

FIG. 12A illustrates a waveform of a first discharge pattern.

FIG. 12B illustrates a waveform of a second discharge pattern.

FIG. 13 illustrates a flowchart of voltage simulation.

FIG. 14 illustrates input/output to/from an arithmetic portion.

### DETAILED DESCRIPTION OF VARIOUS EMBODIMENTS

An overview of a management apparatus is described. (1) A management apparatus according to an embodiment of the present invention periodically executes voltage simulation for an energy storage apparatus. The management apparatus includes an arithmetic portion and a storage portion.

The storage portion stores a discharge pattern made of time series data for discharge current. The discharge pattern includes first time series data and second time series data for the discharge current. The first time series data is time series data for the discharge current, for a predetermined time, and the second time series data is time series data for the discharge current, within a voltage simulation execution period for the energy storage apparatus.

The arithmetic portion periodically executes voltage simulation for estimating a voltage change of the energy storage apparatus when the energy storage apparatus discharges in the discharge pattern, and periodically judges whether the energy storage apparatus can discharge in the discharge pattern, based on the result of the voltage simulation.

According to the management apparatus described in the above (1), the discharge pattern includes second time series data in addition to first time series data of discharge current. The second time series data is time series data for discharge current within a voltage simulation execution period for the energy storage apparatus, and therefore, voltage simulation, taking into consideration discharge within an execution period, becomes possible.

Therefore, due to discharge within an execution period, such misjudgment is restrained in which an energy storage apparatus, which in fact is in a state unable to discharge in a discharge pattern, is misjudged to be capable of discharging in a discharge pattern.

(2) According to the management apparatus described in the above (1), the voltage simulation execution period may be switchable. According to the management apparatus described in the above (2), the execution period is shortened, thereby shortening a judgment period in which whether discharge is possible is judged. Therefore, when the energy storage apparatus transitions from a dischargeable state to a non-dischargeable state, when the energy storage apparatus transitions from a dischargeable state to a non-dischargeable state, the incident can be discovered early. By lengthening the execution period, a calculation load on the arithmetic portion is lowered, to contribute to energy saving.

(3) According to the management apparatus described in the above (2), the energy storage apparatus may be for use in a vehicle. According to the management apparatus according to the above (3), the arithmetic portion may execute the voltage simulation in a first period if the vehicle is in a first state; and may execute the voltage simulation in a second period if the vehicle is in a second state. According to this configuration, the judgment accuracy as to whether discharge is possible can be switched depending on a state of the vehicle.

(4) According to the management apparatus described in the above (3), the first state is while the vehicle is traveling, the second state is while the vehicle is not traveling, and the second period may be longer than the first period. According to the management apparatus described in the above (4), while the vehicle is traveling, voltage simulation is executed in a first period (short period), and therefore if discharge by the energy storage apparatus in a discharge pattern results in a non-dischargeable state, the incident can be discovered early. On the other hand, while the vehicle is not traveling, voltage simulation is executed in second period (long period), and therefore power consumption of the management apparatus can be restrained, to contribute to energy saving.

(5) According to the management apparatus described in the above (3) or (4), the second time series data may be different depending on a state of the vehicle. According to the management apparatus described in the above (5), voltage simulation is executed using the second time series data which depends on the state of the vehicle, and therefore it is possible to restrain any error in estimation of the discharge current within the voltage simulation execution period. Accordingly, highly accurate voltage simulation can be executed.

(6) According to the management apparatus described in the above (5), the first state may be while the vehicle is traveling, and the second state may be while the vehicle is not traveling. The second time series data while the vehicle is not traveling may be smaller than the second time series data while the vehicle is traveling. According to the management apparatus described in the above (5), while the vehicle is traveling, which incurs a large amount of discharge, the value of the second time series data may be set to be large; and while the vehicle is not traveling, which incurs a small amount of discharge, the value of the second time series data may be set to be small. By doing so, an error related to the discharge current (an error between the actual discharge current and the discharge current in the simulation) can be reduced.

(7) According to the management apparatus described in any one of the above (2) to (6), the storage portion may store, as the voltage simulation execution period, a first discharge pattern that includes time series data for a first period and a second discharge pattern that includes time series data for a second period. If the first period is selected, the arithmetic portion may select the first discharge pattern and execute the voltage simulation, and if the second period is selected, the arithmetic portion may select the second discharge pattern and execute the voltage simulation. According to the management apparatus described in the above (7), the discharge pattern is provided for each period. Therefore, regardless of the difference in period, the voltage simulation is highly accurate. Accordingly, the accuracy in judging whether discharge is possible in the discharge pattern can be improved.

(8) According to the management apparatus described in any one of the above (1) to (7), during the voltage simulation, the arithmetic portion may estimate the voltage change of the energy storage apparatus, based on an SOC of the energy storage apparatus, a cell's internal resistance, discharge current, a cell's temperature, and a charge/discharge history. According to the management apparatus described in the above (8), voltage simulation is executed taking into consideration the voltage change in response to change in the SOC, and a voltage change due to the internal resistance, temperature, and charge/discharge history. Accordingly, voltage estimation accuracy and accuracy in judging whether power can be supplied can be heightened.

(9) According to the management apparatus described in any one of the above (1) to (8), the arithmetic portion may execute, in parallel, a plurality of voltage simulations, by using a plurality of discharge patterns. According to the management apparatus described in the above (9), it is possible to judge whether discharge is possible in the plurality of discharge patterns.

(10) An energy storage apparatus according to an embodiment of the present invention includes: a cell; and the management apparatus according to any one of the above (1) to (9). According to the energy storage apparatus described in the above (10), the management apparatus included therein can execute voltage simulation in the discharge pattern.

### First Embodiment

### 1. Description of Battery 50

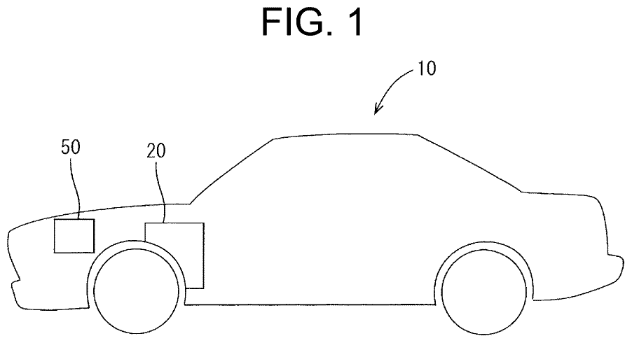

As illustrated in FIG. 1, an engine 20 and a battery 50 are mounted on an automobile 10. The battery 50 is provided for an auxiliary machine of the automobile 10. The battery 50 is an example of “energy storage apparatus”. An energy storage apparatus for driving a vehicle, a fuel cell, etc. may be mounted on the automobile 10.

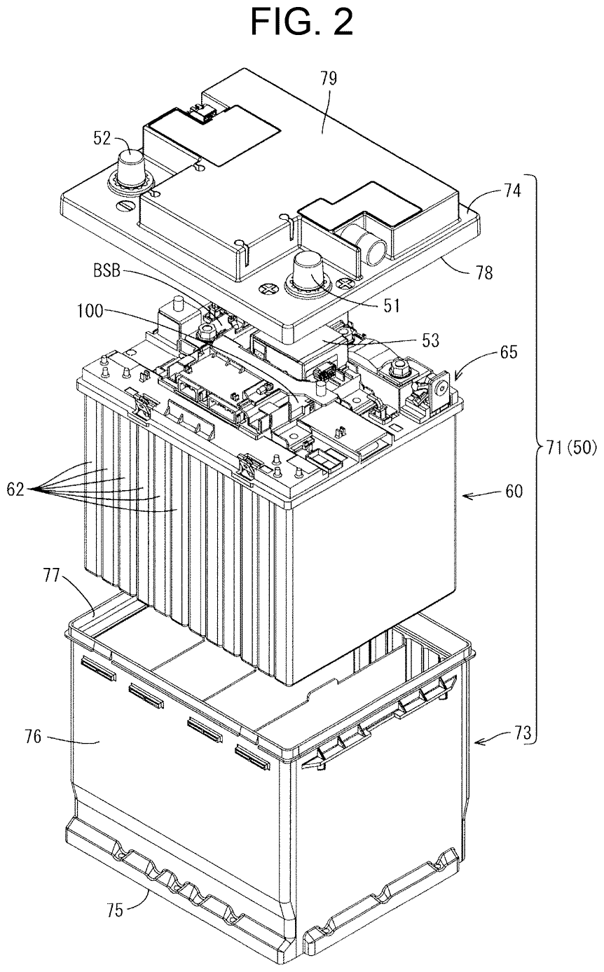

As illustrated in FIG. 2, the battery 50 includes a battery pack 60, a circuit board unit 65, and a housing body 71. The housing body 71 includes a main body 73 and a lid 74, made of a synthetic resin material. The main body 73 has a shape of a cylinder with a bottom, and includes a bottom surface portion 75 and four side surface portions 76. The four side surface portions 76 form an opening portion 77 in an upper end of the main body 73.

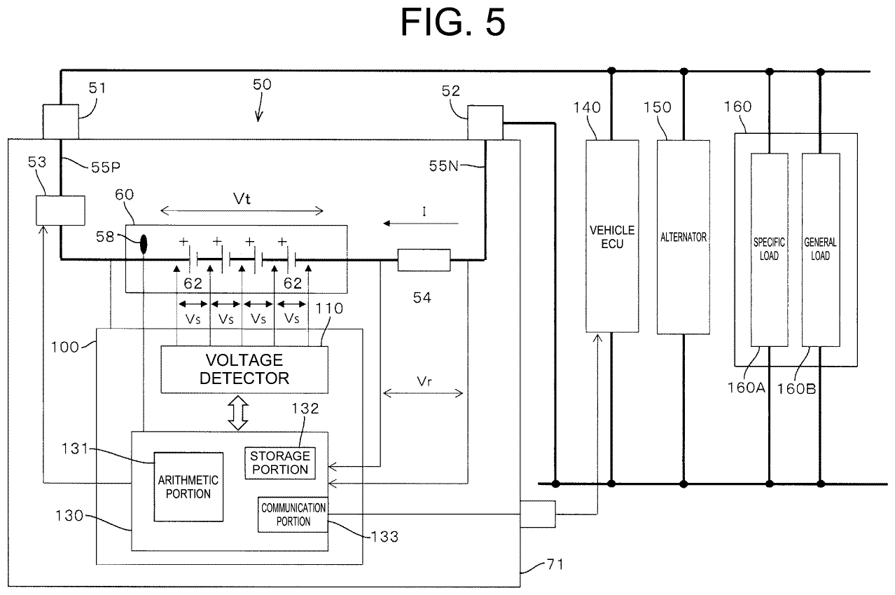

The housing body 71 accommodates therein the battery pack 60 and the circuit board unit 65. The circuit board unit 65 is a board unit including various types of parts (the current interruption apparatus 53, and the current detector 54 and the management apparatus 130, etc., illustrated in FIG. 5) on the circuit board 100, and is provided, for example, being adjacent to an upper part of the battery pack 60, as illustrated in FIG. 2. Alternatively, the circuit board unit 65 may be provided adjacent to a side of the battery pack 60.

The lid 74 closes the opening portion 77 of the main body 73. An outer peripheral wall 78 is provided around the lid 74. The lid 74 includes a protruding portion 79 which is roughly T-shaped in a plan view. A positive electrode external terminal 51 is fixed to one corner portion of a front portion of the of the lid 74, and a negative electrode external terminal 52 is fixed to the other corner portion of the front portion of the of the lid 74. The circuit board unit 65 may be accommodated within the lid 74 (e.g., within the protruding portion 79), instead of within the main body 73 of the housing body 71.

The battery pack 60 is constituted by a plurality of cells 62. As illustrated in FIG. 4, the cell 62 is obtained by accommodating an electrode body 83 together with a non-aqueous electrolyte in a case 82 having a rectangular parallelepiped shape (prismatic shape). The cell 62 is, for example, a lithium-ion secondary battery cell. The case 82 includes a case main-body 84 and a lid 85 which closes an opening portion above the case main-body 84.

Although not illustrated in detail, the electrode body 83 is obtained by disposing a separator made of a porous resin film between a negative electrode plate obtained by applying an active material to a base material made of copper foil and a positive electrode plate obtained by applying an active material to a base material made of aluminum foil. These are all in a band shape, and are wound in a flat shape so as to be able to be accommodated in the case main-body 84, in a state in which the negative electrode plate and the positive electrode plate are respectively shifted in position to opposite sides in the width direction with respect to the separator. The electrode body 83 may be of a laminated type instead of a wound type.

A positive electrode terminal 87 is connected to the positive electrode plate via a positive electrode current collector 86, and a negative electrode terminal 89 is connected to the negative electrode plate via a negative electrode current collector 88. The positive electrode current collector 86 and the negative electrode current collector 88 each include a pedestal portion 90 having a flat plate shape, and a leg portion 91 extending from this pedestal portion 90. A through hole is formed in the pedestal portion 90. The leg portion 91 is connected to the positive electrode plate or the negative electrode plate.

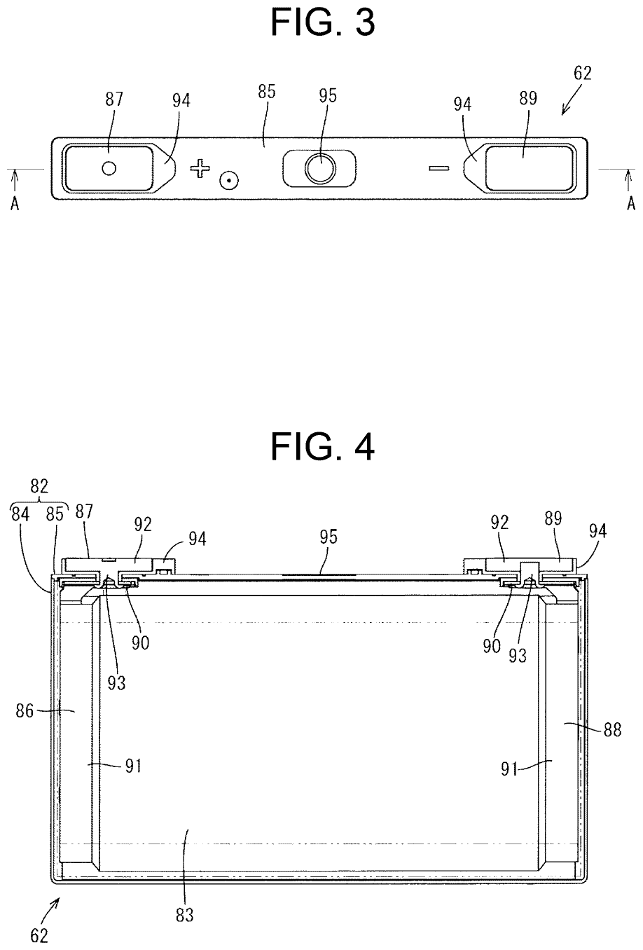

Each of the positive electrode terminal 87 and the negative electrode terminal 89 includes a terminal main-body portion 92 and a shaft portion 93 protruding downward from a central portion of a lower surface of the terminal main-body portion 92. The terminal main-body portion 92 and the shaft portion 93 of the positive electrode terminal 87 are integrally formed of aluminum (a single material). In the negative electrode terminal 89, the terminal main-body portion 92 is made of aluminum, the shaft portion 93 is made of copper, and these are assembled. The terminal main-body portions 92 of the positive electrode terminal 87 and the negative electrode terminal 89 are disposed at both end portions of the lid 85 via gaskets 94 made of an insulating material, and are exposed outward from the gaskets 94, as illustrated in FIG. 3.

The lid 85 includes a pressure release valve 95. The pressure release valve 95 is positioned between the positive electrode terminal 87 and the negative electrode terminal 89. The pressure release valve 95 is a safety valve. When the internal pressure of the case 82 exceeds a limit, the pressure release valve 95 is opened to lower the internal pressure of the case 82.

FIG. 5 is a block diagram illustrating an electrical configuration of the battery 50. The battery 50 includes a battery pack 60, a current detector 54, a current interruption apparatus 53, a voltage detector 110, a temperature sensor 58, and a management apparatus 130.

A vehicle electronic control unit (ECU) 140, an alternator 150, which is a generator that generates power by using power of the engine 20, and an auxiliary machine 160 of the automobile 10 are electrically connected to the battery 50. The vehicle ECU 140 is a vehicle control unit that controls the automobile 10.

The vehicle ECU 140 controls the alternators 150 and the auxiliary machines 160. The vehicle ECU 140 may also control a drive system such as an engine. The number of vehicle ECUs 140 is not limited to one, and may be two or more.

The auxiliary machine 160 includes a specific load 160A and a general load 160B. The specific load 160A is a target load of voltage simulation to be described later. The general load 160B includes, for example, a headlight, a wiper, a car navigation system, an air conditioner, and the like.

When the amount of power generated by the alternator 150 is larger than the amount of power consumed by the auxiliary machines 160 during driving of the engine 20, the battery 50 is charged by the alternator 150. When the amount of power generated by the alternator 150 is smaller than the amount of power consumed by the auxiliary machines 160, the battery 50 discharges to compensate for the shortage.

While the engine 20 is stopped, the alternator 150 stops power generation. While the power generation is stopped, the battery 50 is in a state of not being charged, and is in a state of performing only discharge to the vehicle ECU 140 and the auxiliary machine 160.

There are, for example, twelve cells 62 in the battery pack 60 (refer to FIG. 2), and the cells 62 are connected such that three cells 62 are connected in parallel and four cells 62 are connected in series. FIG. 5 illustrates three cells 62 connected in parallel by one battery symbol. The cell 62 is an example of an “energy storage cell”.

The energy storage cell is not limited to a prismatic cell, and may be a cylindrical cell or a pouch cell having a laminate film case. The battery 50 has a 12 V rated voltage.

The battery pack 60, the current interruption apparatus 53, and the current detector 54 are connected in series via the power line 55P and the power line 55N. As the power lines 55P and 55N, bus bars BSB (refer to FIG. 2), which are plate-shaped conductors made of a metallic material such as copper, can be used.

As illustrated in FIG. 5, the power line 55P connects the positive electrode external terminal 51 and the positive electrode of the battery pack 60. The power line 55N connects the negative electrode external terminal 52 and the negative electrode of the battery pack 60. The external terminals 51 and 52 are connecting terminals of the battery 50 to the automobile 10 (the auxiliary machines 160). The battery 50 can be electrically connected to the alternator 150 and the auxiliary machine 160 via the external terminals 51 and 52.

The current interruption apparatus 53 is provided in a positive electrode power line 55P. The current interruption apparatus 53 may be a semiconductor switch such as an FET, or may be a relay having a mechanical contact. The current interruption apparatus 53 is preferably a self-holding switch such as a latch relay.

The current interruption apparatus 53 is of a normally-closed type, and is controlled to be in a closed state in a normal state. When there is some abnormality in the battery 50, the current of the battery pack 60 can be interrupted by switching the current interruption apparatus 53 from the closed state to the open state.

The current detector 54 is provided in the negative electrode power line 55N. The current detector 54 may be a shunt resistor. The resistive current detector 54 can measure current I of the battery pack 60, based on a voltage Vr between both ends of the current detector 54. The resistive current detector 54 can distinguish between discharging and charging, based on the voltage polarity (positive or negative). Alternatively, the current detector 54 may be a magnetic sensor.

The voltage detector 110 can detect a voltage Vs of the cell 62 and a total voltage Vt of the battery pack 60. The temperature sensor 58 is attached to the battery pack 60, and detects a battery temperature TS of the battery pack 60 or a temperature TS around the battery pack 60.

The management apparatus 130 is mounted on the circuit board 100 (refer to FIG. 2), and includes an arithmetic portion 131 such as a CPU, a storage portion 132, and a communication portion 133, as illustrated in FIG. 5.

The communication portion 133 is connected to the vehicle ECU 140 via a signal line, and communicates with the vehicle ECU 140. The management apparatus 130 can receive a signal regarding an operation state (during traveling, stopping, parking, or the like) of the automobile 10 from the vehicle ECU 140 through communication.

The management apparatus 130 monitors the state of the battery 50, based on the outputs of the voltage detector 110, the current detector 54, and the temperature sensor 58. That is, the battery temperature TS, the current I, and the total voltage Vt of the battery pack 60 are monitored.

The management apparatus 130 estimates the SOC [%] of the battery pack 60 based on the current I of the battery pack 60.

The SOC (state of charge) is a ratio of a remaining capacity to a full-charge capacity, and is expressed by the following expression (1).

$$SOC = ( Cr / Co ) \times 100 \qquad ( 1 )$$

Co is a full-charge capacity of the cell, and Cris a remaining capacity of the cell.

The SOC can be estimated based on an integral value of the current I with respect to time, as expressed by the following expression (2). The sign of the current I is positive during charging and negative during discharging.

$$SOC = SOCo + 100 \times ( \int Idt / Co ) \qquad ( 2 )$$

SOCo is an initial value of the SOC, and I is a current.

The storage portion 132 stores an execution program of the voltage simulation and data necessary to execute the program. The data stored in the storage portion 132 includes data of a discharge pattern P to be described later. Further, data of the internal resistance R of the battery pack 60 and data of a charge/discharge history of the battery 50 are included.

The program may be stored in a recording medium such as a CD-ROM to be used, transferred, lent, or the like. The program may be distributed by using a telecommunication line.

### 2. Voltage Simulation

The voltage simulation is to estimate a temporal change of the total voltage Vt of the battery pack 60 by using the discharge pattern P.

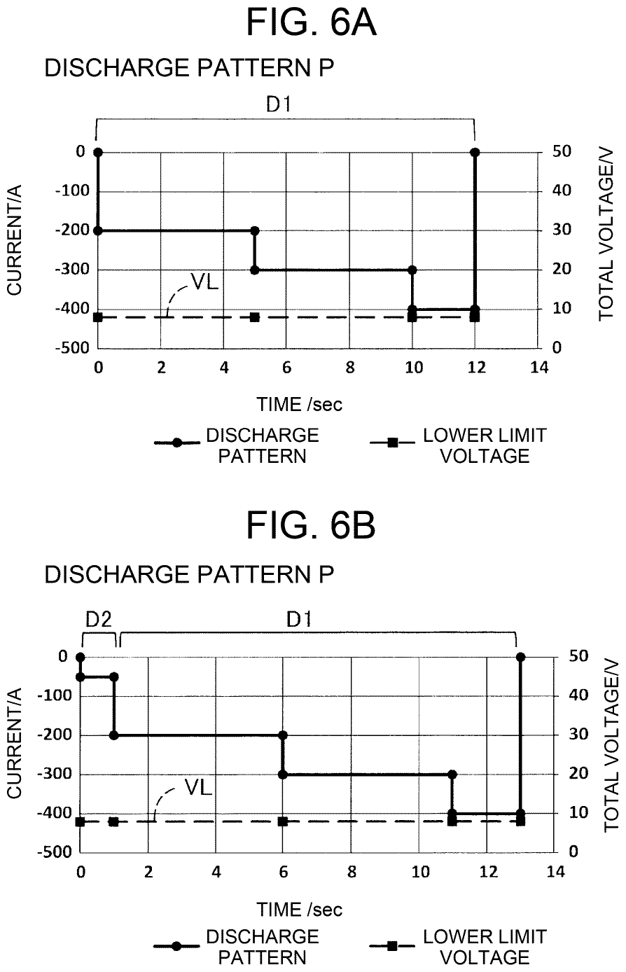

The discharge pattern P is the first time series data D1 of the discharge current for a predetermined time. For example, the discharge pattern P in FIG. 6A is data of discharge current for 12 seconds represented by a graph in which the horizontal axis represents time and the vertical axis represents discharge current. The discharge pattern P is, as an example, discharge current necessary for the operation of the specific load 160A, and when the operation time of the specific load 160A is 12 seconds, the discharge pattern P is data for 12 seconds.

By the voltage simulation, total voltage Vt0 to Vt12, when the battery 50 is discharged for 12 seconds according to the discharge pattern P, that is, when the battery 50 is discharged for 12 seconds with respect to the specific load 160A, is obtained.

By comparing the total voltage Vt0 to Vt12 with the lower limit voltage VL of the total voltage Vt, it is possible to judge whether the battery 50 can be discharged in the discharge pattern P, that is, whether power to operate the specific load 160A can be supplied to the specific load 160A.

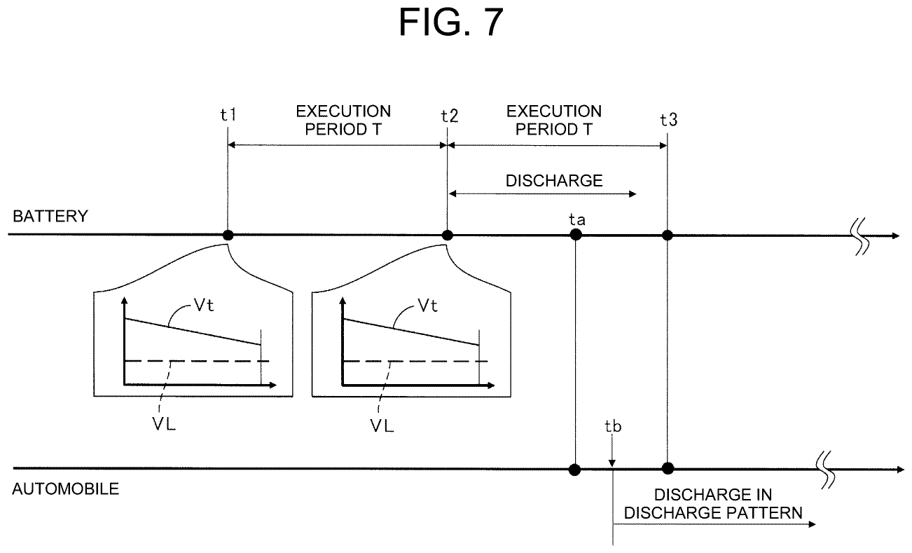

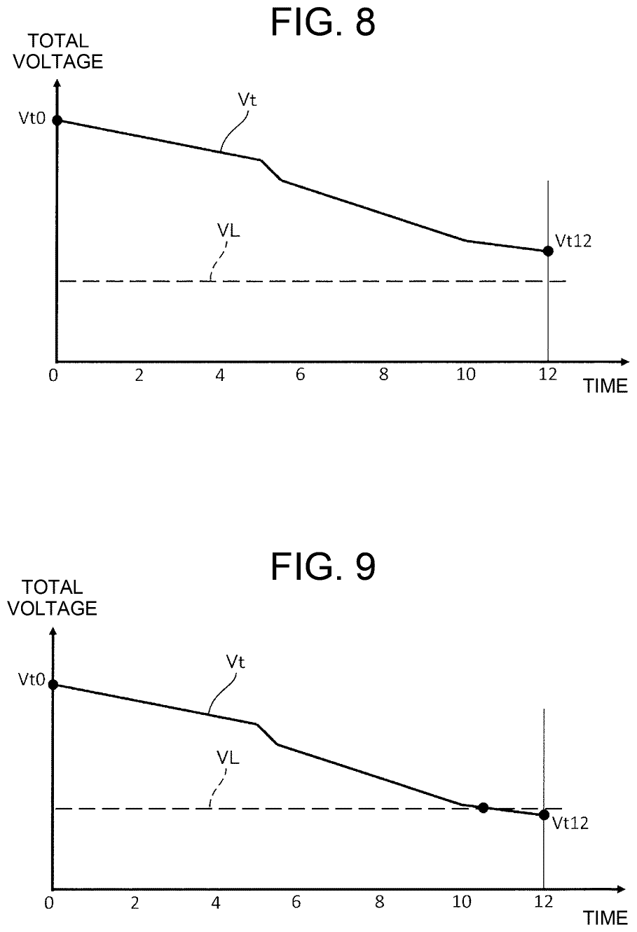

FIG. 7 illustrates a time line of the voltage simulation, and FIG. 8 illustrates a simulation result. According to the simulation result of FIG. 8, the total voltage Vt0 to Vt12 is equal to or higher than the lower limit voltage VL. Therefore, in this case, it is judged that the battery 50 can discharge in the discharge pattern P, that is, can supply power to the specific load 160A (the specific load 160A is operable).

On the other hand, when a part of the total voltage Vt0 to Vt12 falls below the lower limit voltage VL (Vt<VL), it is judged that discharge in the discharge pattern P is impossible, i.e., power cannot be supplied to the specific load 160A (the specific load 160A is inoperable).

As illustrated in FIG. 7, by periodically executing the voltage simulation (t1, t2, t3, and . . . ), whether discharge in the discharge pattern P is possible can be periodically confirmed.

When discharge in the discharge pattern P is impossible, the battery 50 can be returned to a state in which power can be supplied to the specific load 160A by prompting the vehicle ECU 140 to charge.

The specific load 160A is, as an example, a safety-related load such as an electric brake or electric steering, and in the present embodiment, voltage simulation is executed for the purpose of functional safety of an automobile. By executing the voltage simulation for the safety-related load, it is possible to determine whether power can be supplied from the battery 50 to the safety-related load during a period (for example, about one minute) until the automobile stops when the vehicle power generation system (DCDC or alternator) fails during automatic driving. The voltage simulation can be used not only for functional safety but also for other applications and purposes such as ensuring comfort.

As a result of the voltage simulation, for example, when the judgment at the time point t2 in FIG. 7 indicates that discharge is possible (when Vt>VL), the management apparatus 130 determines that discharge is possible (power can be supplied to the specific load 160A) in the discharge pattern in the period t2 to t3 until the next judgment.

However, when considering discharge within the voltage simulation execution period T, there is a possibility that discharge in the discharge pattern P is impossible (misjudgment in judgment as to whether discharge is possible).

To be more specific, the battery 50 may be discharged not only to a specific load 160A, which is a target of voltage simulation, but also to a general load 160B. Depending on the type of the general load 160B, discharge may be performed all the time.

When there is discharge to the general load 160B (the same applies to a case where discharge is performed to a load other than the general load 160B, such as the specific load 160A), the energy storage amount of the battery 50 decreases also within the voltage simulation execution period T.

For example, at time t2, even in a state in which discharge in the discharge pattern P is possible and the total voltage Vt12 after discharge has a margin with respect to the lower limit voltage VL, on or after t2, the margin with respect to the lower limit voltage VL decreases due to discharge within the execution period T. When there is no margin at the time point of time ta, the total voltage Vt may fall lower than the lower limit voltage VL if discharge is performed in the discharge pattern P in a period from the time ta to the next judgment time point of time t3.

FIG. 9 illustrates a change in the total voltage Vt when discharge in the discharge pattern P is started at time tb. In this example, at a time point 10 seconds to 11 seconds after the discharge start at the time tb, the total voltage Vt falls below the lower limit voltage VL, and the battery 50 has reached a depleted state.

In order to solve such a problem, the management apparatus 130 uses an improved discharge pattern P in the voltage simulation.

As illustrated in FIG. 6B, the improved discharge pattern P is obtained by adding second time series data D2 to first time series data D1. That is, the discharge time is set to the total time of the first time series data D1 and the second time series data D2, and the discharge pattern is set to cause discharge more by an amount corresponding to the second time series data D2, compared to a case where discharge is performed only in the first time series data D1.

The second time series data D2 is time series data of discharge current discharged from the battery 50 to the general load 160B, or the like, within the execution period T. As the second time series data D2, a past actual value (fixed value) may be used, or discharge current in the previous period T may be used. Further, switching may be performed depending on the operation state of the automobile 10. In the present embodiment, the discharge current is set to a fixed value of about 50 A.

The improved discharge pattern P is data that is longer by one period than the discharge pattern P before improvement. The first time series data D1 is 12 seconds, the execution period T is 1 second, and the discharge pattern P is 13 seconds.

In the present embodiment, the second time series data D2 is added before the first time series data D1 (to the left of FIG. 6B), however may alternatively be added after the first time series data D1 (to the right of FIG. 6B).

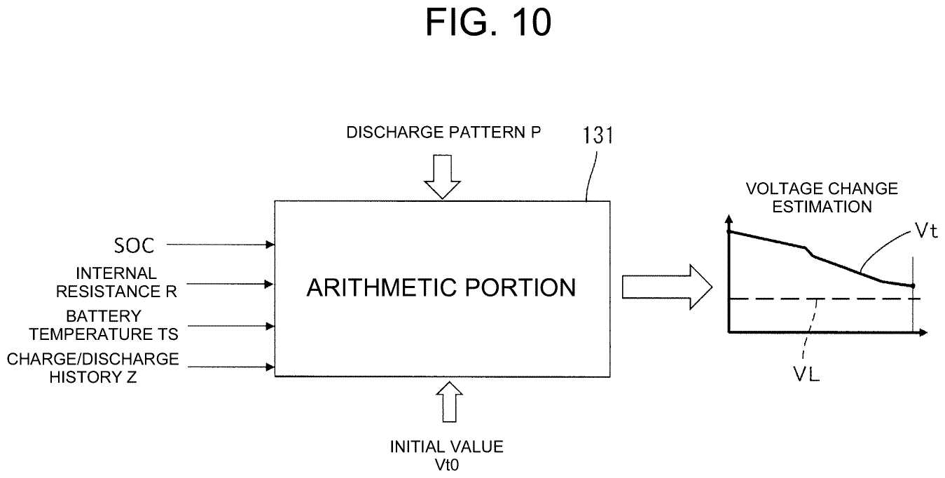

As illustrated in FIG. 10, the arithmetic portion 131 receives (A) to (F) as inputs, and estimates the temporal change of the total voltage Vt of the battery pack 60 when discharge is performed in the discharge pattern P (voltage simulation).

Specifically, as indicated by expression (3), the voltage change amount ΔV of the total voltage due to the discharge in the discharge pattern P is subtracted from the initial value Vt0 of the total voltage, thereby estimating the temporal change of the total voltage Vt.

The voltage change amount ΔV can be calculated based on information on the SOC, the internal resistance R, the battery temperature TS, and the charge/discharge history Z of the battery pack 60, and the like. ΔV may be calculated by using a predetermined arithmetic expression or may be calculated by using a reference table.

$$Vt = Vt 0 - Δ V ( SOC , R , I , TS , Z ) \qquad Expression ( 3 )$$

Vt is a total voltage, Vt0 is an initial value of the total voltage, ΔV is a voltage change amount, R is an internal resistance of the battery pack, I is discharge current to a specific load, and TS is a battery temperature. Z is a charge/discharge history of the battery 50.
(A) Improved discharge pattern P
(B) Initial value Vt0 of total voltage of battery pack 60
(C) SOC of battery pack 60
(D) Internal resistance R of battery pack 60
(E) Battery temperature TS
(F) Charge/discharge history Z of battery 50

A measured value of the voltage detector 110 is used as Vt0, and a measured value of the temperature sensor 58 is used as TS. As the SOC, a calculated value, which is calculated by a current integration method is used. Data of the discharge pattern is used as I. As the internal resistance R, a fixed value (empirical value) stored in the storage portion 132 may be used, or a calculated value obtained based on the measured values I and Vt of the current detector 54 and the voltage detector 110 may be used.

The reason why the battery temperature TS is included in the input values of the voltage simulation is to perform temperature correction on the internal resistance R. When the temperature correction is not performed, the battery temperature TS may be omitted from the inputs.

The reason why the charge/discharge history Z (the number of times of charge/discharge, or the like) of the battery 50 is included in the input values of the voltage simulation is to consider an increase in the internal resistance R due to deterioration of the battery 50. When deterioration of the battery 50 is not considered, the charge/discharge history Z may be omitted from the input.

In the present embodiment, the specific load 160A is a safety-related load such as an electric brake or electric steering, however may be a door lock device or a device that switches an operation mode of the automobile 10. The specific load 160A may also be an apparatus used for emergency evacuation traveling.

### 3. Advantageous Effects

By using the discharge pattern P to which the second time series data D2 is added in the voltage simulation, by the discharge of the battery 50 within the execution period T, such misjudgment is restrained, in which the battery 50, which in fact is in a state unable to discharge in a discharge pattern P, is misjudged to be capable of discharging. Therefore, it is possible to accurately judge whether discharge is possible in the discharge pattern P.

### Second Embodiment

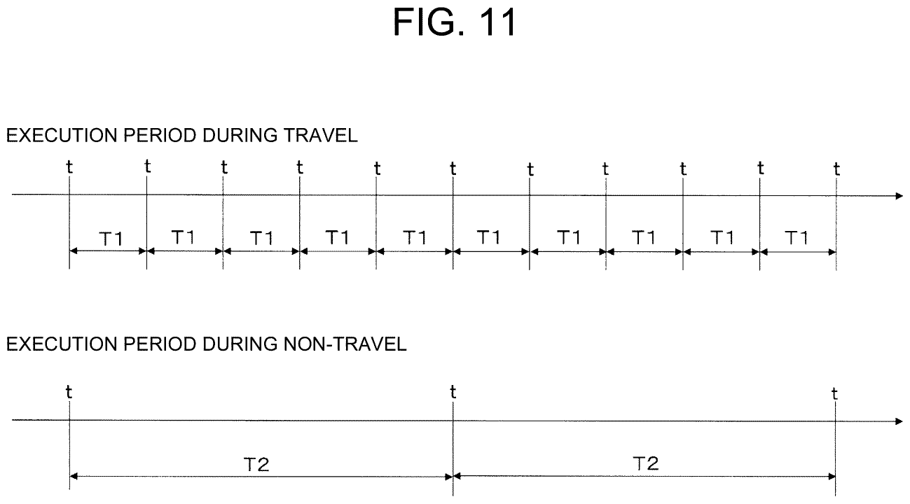

In the second embodiment, as illustrated in FIG. 11, the voltage simulation execution period T includes two periods, i.e., a first period T1 and a second period T2, and the execution period T can be switched.

T1 is a short period. By selecting T1, a judgment period in which whether discharge is possible in the discharge pattern P is judged is shortened, and therefore, when the battery 50 transitions from a dischargeable state to a non-dischargeable state, the incident can be discovered early.

T2 is a long period. By selecting T2, the calculation load of the management apparatus 130 can be reduced, and power consumption can be suppressed.

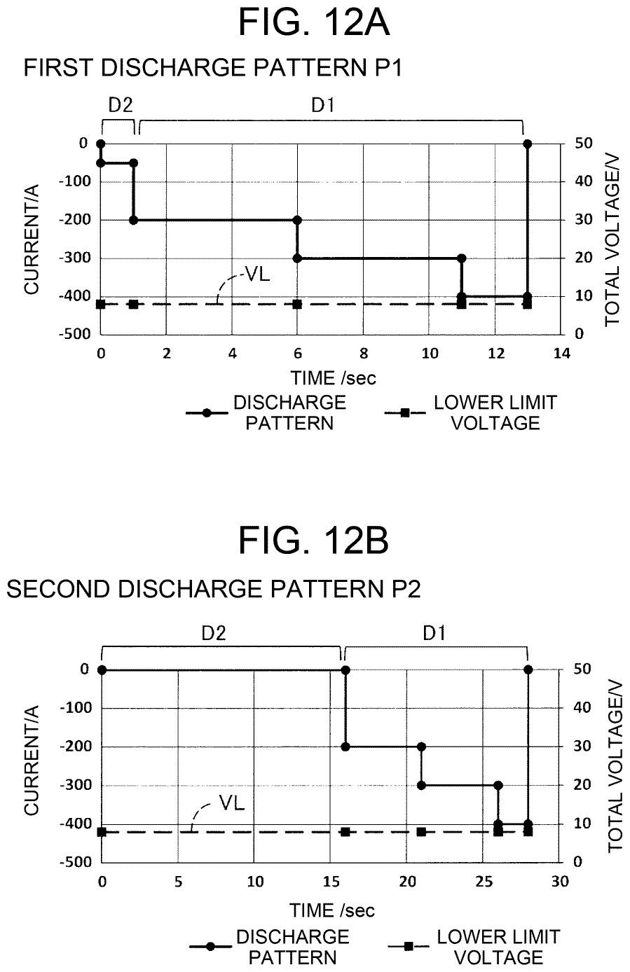

The storage portion 132 stores a first discharge pattern P1 and a second discharge pattern P2. FIG. 12A illustrates a waveform of the first discharge pattern P1, and FIG. 12B illustrates a waveform of the second discharge pattern P2.

Each of the first discharge pattern P1 and the second discharge pattern P2 is constituted by the first time series data D1 and the second time series data D2.

The first discharge pattern P1 is for T1 (short period), and the second discharge pattern P2 is for T2 (long period). Two discharge patterns P1 and P2 differ in second time series data D2 due to a difference in period. Specifically, the data length (discharge time) and the current value are different.

Further, the two discharge patterns P1 and P2 are used to judge whether power can be supplied to a same specific load 160A, and the first time series data D1 is common between them.

In the present embodiment, the execution period T and the discharge pattern P are switched according to the state of the automobile 10, and as illustrated in FIG. 12, the first discharge pattern P1 is selected and the voltage simulation is executed in the first period T1 while the automobile 10 is traveling; and the second discharge pattern P2 is selected and the voltage simulation is executed in the second period T2 while the automobile 10 is not traveling.

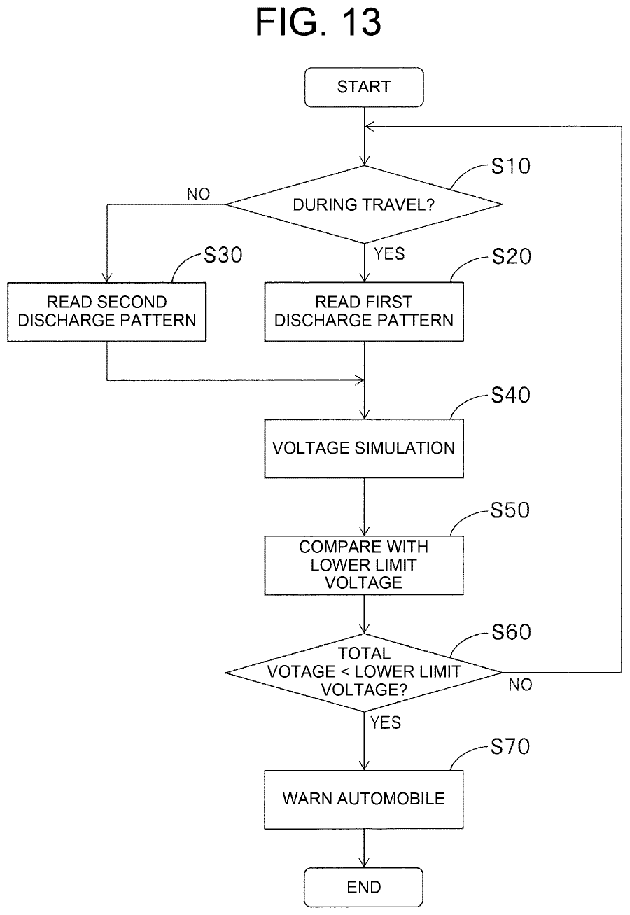

FIG. 13 is a flowchart of the voltage simulation. The execution process of the voltage simulation includes seven steps of S10 to S70.

After the management apparatus 130 is activated, the process proceeds to S10, and the arithmetic portion 131 judges whether the operation state of the automobile 10 indicates that the automobile 10 is traveling. The operation state of the automobile 10 can be judged by communication with the vehicle ECU 140. The operation state of the automobile 10 can also be judged by the current I of the battery 50.

When the automobile 10 is traveling, the process proceeds to S20, and the arithmetic portion 131 reads the first discharge pattern P1 from the storage portion 132.

Thereafter, the arithmetic portion 131 performs voltage simulation by using the first discharge pattern P1, and estimates a voltage change of the total voltage Vt of the battery pack 60 when discharge is performed in the first discharge pattern P1 (S40).

After executing the voltage simulation, the arithmetic portion 131 compares the total voltage Vt of the battery pack 60 with the lower limit voltage VL (S50).

In the case of Vt≥VL (S60: NO), the arithmetic portion 131 judges that “discharge is possible in the first discharge pattern P1”. Thereafter, the process returns to S10.

While the automobile 10 is traveling, the execution process of the voltage simulation (S10, S20, S40, S50, and S60) is executed in the first period T1.

When the automobile 10 proceeds to a non-travel state, such as stopping or parking, a judgment of NO is made in S10, the process proceeds to S30, and the arithmetic portion 131 reads the second discharge pattern P2 from the storage portion 132.

Thereafter, the arithmetic portion 131 performs voltage simulation using the read second discharge pattern P2, and estimates a voltage change of the total voltage Vt of the battery pack 60 when discharge is performed in the second discharge pattern P2 (S40).

The arithmetic portion 131 compares the total voltage Vt of the battery pack 60 with the lower limit voltage VL, and judges whether discharge by the second discharge pattern P2 is possible (S50, S60).

When the automobile 10 is not traveling, the execution process of the voltage simulation (S10, S30, S40, S50, S60) is executed in the second period T2.

In both cases of the automobile 10 traveling and not traveling, if Vt<VL as a result of the voltage simulation (S60: YES), the arithmetic portion 131 judges that “the battery 50 cannot discharge in the discharge pattern P”

In this case, the process proceeds to S70, and the management apparatus 130 notifies the vehicle ECU 140 of warning information and prompts charge of the battery 50.

The total voltage Vt of the battery 50 increases due to the charge, and the battery 50 returns to a state in which discharge in the first discharge pattern P1 or the second discharge pattern P2 is possible.

In the present embodiment, since the voltage simulation is executed in the short period T1 when the automobile 10 is traveling, when the battery 50 has reached a state in which discharge in the first discharge pattern P1 is impossible, the incident can be discovered early.

On the other hand, since the voltage simulation is executed in the long period T2 while the automobile 10 is not traveling, it is possible to suppress power consumption of the management apparatus 130 to contribute to energy saving.

### Third Embodiment

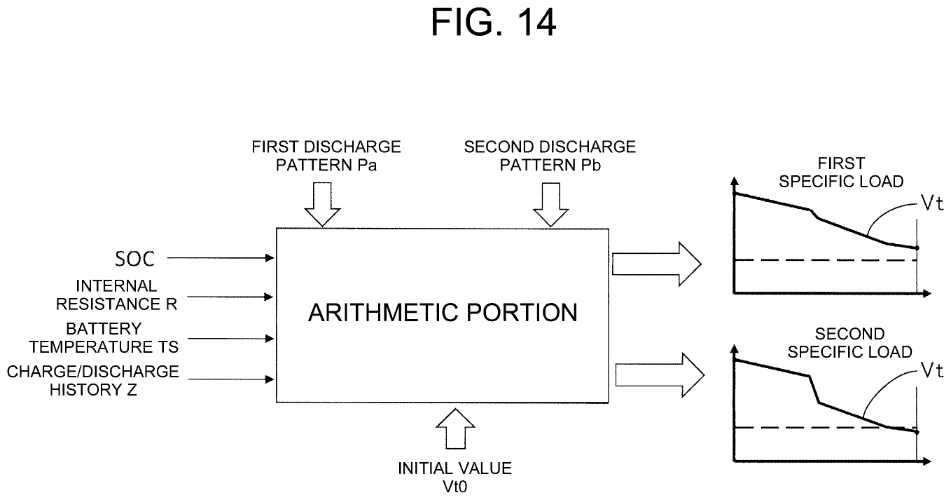

In the third embodiment, as illustrated in FIG. 14, two discharge patterns Pa and Pb are used in the voltage simulation. For example, the first discharge pattern Pa is for a first specific load (emergency communication apparatus), and the second discharge pattern Pb is for a second specific load (hazard lamp).

The discharge patterns Pa and Pb differ in the first time series data D1, however are common in the second time series data D2. The reason why the first time series data D1 is different is that the specific load to be supplied with power is different.

The arithmetic portion 131 uses the two discharge patterns, i.e., discharge patterns Pa and Pb, to perform two patterns of voltage simulation in parallel. By performing the two patterns of voltage simulation in parallel, it is possible to determine whether or not discharge by the two types of discharge patterns Pa and Pb is possible.

In the case of the above example, it is possible to determine whether power can be supplied to the first specific load (emergency communication apparatus) and whether power can be supplied to the second specific load (hazard lamp).

According to this configuration, a discharge pattern of the battery 50 can be selected, which can be useful for discharge control of the battery 50 and vehicle load control by the vehicle ECU 140.

In the present embodiment, since the two discharge patterns Pa and Pb are stored, it is also possible to perform voltage simulation in which discharge is performed in the two discharge patterns simultaneously (i.e., power is simultaneously supplied to a plurality of specific loads), thereby to determine whether simultaneous discharge in the plurality of discharge patterns Pa and Pb is possible (whether simultaneous power supply to the plurality of specific loads is possible).

### Other Embodiments

The present invention is not limited to the embodiment explained with reference to the above description and the drawings, and the technical scope of the present invention also incorporates the following embodiments.

(1) The energy storage cell 62 is not limited to a lithium-ion secondary battery, and may be any other non-aqueous electrolyte secondary battery. The energy storage cell 62 is not limited to a case where a plurality of energy storage cells 62 are connected in series-parallel, and may be connected in series or may be a single cell. A capacitor can also be used instead of the energy storage cell 62.

(2) In the above-described embodiment, the battery 50 is mounted on the automobile 10, however may be mounted on a mobile body other than a vehicle, such as a ship or an aircraft. Further, the battery (energy storage apparatus) 50 is not limited to be used in a mobile body, however may also be used in a stationary application, such as for use in an energy storage apparatus for absorbing fluctuation in a distributed energy generation system.

(3) In the above-described embodiment, the management apparatus 130 is provided inside the battery 50. The battery 50 may include at least instruments such as the current detector 54 and the voltage detector 110, and the management apparatus 130 and the current interruption apparatus 53 may be provided outside the battery 50.

(4) In the above-described second embodiment, the discharge patterns P1 and P2 are provided for the execution periods T1 and T2, respectively, however the discharge pattern P may be common. For example, the time series data may have: as the period, an average period Tav obtained by averaging T1 and T2; and, as the discharge current within the period, an average current Iav obtained by averaging discharge currents I1 and I2 in T1 and T2.

(5) The second time series data D2 of the discharge pattern P may be different depending on the state of the automobile 10. For example, while the vehicle is traveling, which incurs a large amount of discharge, the value of the second time series data D2 may be set to be large (the first discharge pattern P1 illustrated in FIG. 12A); and while the vehicle is not traveling, which incurs a small amount of discharge, the value of the second time series data D2 may be set to be small (the second discharge pattern P2 illustrated in FIG. 12B). By doing so, an error related to the discharge current (an error between the actual discharge current and the discharge current in the simulation) can be reduced.

(6) The purpose of discharge regarding the first time series data D1 of the discharge pattern P does not matter as long as the first time series data D1 of the discharge pattern P is time series data of discharge current for a predetermined time. As illustrated in the embodiments, the purpose may be to discharge to the specific load 160A, or may be to discharge to a load other than the specific load 160A, i.e., such as a vehicle ECU 140 or a general load 160B. The purpose may also be to discharge to a plurality of loads.

1. A management apparatus that periodically executes voltage simulation for an energy storage apparatus, the management apparatus comprising:
an arithmetic portion; and
a storage portion,
the storage portion storing a discharge pattern including time series data for discharge current,
the discharge pattern including first time series data and second time series data for the discharge current,
the first time series data being time series data for the discharge current, for a predetermined time, and
the second time series data being time series data for the discharge current, within a voltage simulation execution period for the energy storage apparatus,
wherein the arithmetic portion periodically executes voltage simulation for estimating a voltage change of the energy storage apparatus when the energy storage apparatus discharges in the discharge pattern, and periodically judges whether the energy storage apparatus can discharge in the discharge pattern, based on a result of the voltage simulation.

2. The management apparatus according to claim 1, wherein the voltage simulation execution period is switchable.

3. The management apparatus according to claim 2, wherein:
the energy storage apparatus is for use in a vehicle, and
the arithmetic portion executes the voltage simulation in a first period if the vehicle is in a first state; and executes the voltage simulation in a second period if the vehicle is in a second state.

4. The management apparatus according to claim 3, wherein:
the first state is while the vehicle is traveling, the second state is while the vehicle is not traveling, and
the second period is longer than the first period.

5. The management apparatus according to claim 3, wherein
the second time series data is different depending on a state of the vehicle.

6. The management apparatus according to claim 5, wherein:
the first state is while the vehicle is traveling, and the second state is while the vehicle is not traveling, and
the second time series data while the vehicle is not traveling is smaller than the second time series data while the vehicle is traveling.

7. The management apparatus according to claim 2, wherein:
the storage portion stores, as the voltage simulation execution period, a first discharge pattern that includes time series data for a first period and a second discharge pattern that includes time series data for a second period, and
if the first period is selected, the arithmetic portion selects the first discharge pattern and executes the voltage simulation; and if the second period is selected, the arithmetic portion selects the second discharge pattern and executes the voltage simulation.

8. The management apparatus according to claim 1, wherein, during the voltage simulation, the arithmetic portion estimates the voltage change of the energy storage apparatus, based on an SOC of the energy storage apparatus, a cell's internal resistance, discharge current, a cell's temperature, and a charge/discharge history.

9. The management apparatus according to claim 1, wherein the arithmetic portion executes, in parallel, a plurality of voltage simulations, including the said voltage simulation, by using a plurality of discharge patterns, including the said discharge pattern, in which the first time series data differs from one another.

10. An energy storage apparatus comprising:
a cell; and
the management apparatus according to claim 1.

11. A voltage simulation method, comprising:
periodically executing voltage simulation for estimating a voltage change of the energy storage apparatus when the energy storage apparatus discharges in a discharge pattern; and
periodically judging whether the energy storage apparatus can discharge in the discharge pattern, based on a result of the voltage simulation,
the discharge pattern including first time series data and second time series data for discharge current,
the first time series data being time series data for the discharge current, for a predetermined time, and
the second time series data being time series data for the discharge current, within a voltage simulation execution period for the energy storage apparatus.
